(19) United States
(12) Patent Application Publication
(10) Pub. No.: US 2024/0172514 A1
(43) Pub. Date: May 23, 2024

(54) DISPLAY DEVICE AND ELECTRONIC DEVICE

(71) Applicant: SONY GROUP CORPORATION, TOKYO (JP)

(72) Inventors: HARUKI TSUCHIYA, TOKYO (JP); KEI KIMURA, TOKYO (JP); TETSUO MINAMI, TOKYO (JP)

(21) Appl. No.: 18/551,295

(22) PCT Filed: Mar. 11, 2022
(86) PCT No.: PCT/JP2022/011036

§ 371 Date: Sep. 19, 2023

(30) Foreign Application Priority Data
Mar. 31, 2021 (JP) 2021-061658

(51) Int. Cl. H10K 59/35

(52) U.S. Cl. CPC H10K 59/353

(57) ABSTRACT

Provided are a display device and an electronic device that can suppress complication of an internal structure and facilitate effective reduction in an amount of processed data in consideration of human vision in a display region. A display device includes a display unit having a display region in which a plurality of pixel columns is arranged. Each of the plurality of pixel columns has a plurality of pixels arranged in a ring shape. In the display unit, the plurality of pixel columns is concentrically arranged along a plane direction of the display region, around, as a center, a reference position in the display region. In a case where a pixel column arranged at a predetermined position in the plurality of pixel columns is defined as a reference pixel column and a pixel forming the reference pixel column is defined as a reference pixel, a pixel forming a pixel column arranged on an outer side of the reference pixel column has a similar shape obtained by enlarging a shape of the reference pixel.

### TECHNICAL FIELD

The present disclosure relates to a display device and an electronic device using the display device.

### BACKGROUND ART

In display devices exemplified by virtual reality (VR), a head mounted display (HMD), and the like (hereinafter, simply referred to as display devices), an amount of processed data increases as a resolution increases. Therefore, the display device is required to reduce an amount of processed data while allowing a person to perceive high-resolution display.

Patent Document 1 proposes a display device including a screen in which pixels are arranged in an X-axis direction and a Y-axis direction orthogonal to each other, in which an area of pixels in a peripheral region of the screen is larger than an area of pixels in a center region of the screen. Patent Documents 2 and 3 propose: a display device that forms a central field of view and a peripheral field of view; and a display device having an optical system and a line-of-sight detection unit.

### CITATION LIST

### Patent Document

Patent Document 1: Japanese Patent Application Laid-Open No. H6-251712

Patent Document 2: Japanese Patent Application Laid-Open No. 2019-091051

Patent Document 2: Japanese Patent Application Laid-Open No. 2019-106723

### SUMMARY OF THE INVENTION

### Problems to be Solved by the Invention

In the display device of Patent Document 1, there is room for improvement in terms of effective reduction of an amount of processed data in consideration of human vision in a display region. Furthermore, the display device of Patent Document 2 has room for improvement in terms of suppressing complication of an internal structure of the display device.

The present disclosure has been made in view of the above points, and an object thereof is to provide a display device and an electronic device that can suppress complication of an internal structure and facilitate effective reduction in an amount of processed data in consideration of human vision in a display region.

### Solutions to Problems

The present disclosure is, for example, (1) a display device including:
a display unit having a display region in which a plurality of pixel columns is arranged, in which
each of a plurality of the pixel columns has a plurality of pixels arranged in a ring shape,
in the display unit, a plurality of the pixel columns is concentrically arranged along a plane direction of the display region, the plurality of the pixel columns being arranged around, as a center, a reference position in the display region, and
in a case where a pixel column arranged at a predetermined position in a plurality of the pixel columns is defined as a reference pixel column, and each of the pixels forming the reference pixel column is defined as a reference pixel,
a pixel forming each of the pixel columns arranged on an outer side of the reference pixel column has a similar shape obtained by enlarging a shape of the reference pixel.

Furthermore, the present disclosure is (2) a display device including:
a display unit having a display region in which a plurality of pixel columns is arranged, in which
each of a plurality of the pixel columns has a plurality of pixels arranged in a ring shape,
in the display unit, a plurality of the pixel columns is concentrically arranged along a plane direction of the display region, the plurality of the pixel columns being arranged around, as a center, a reference position in the display region,
in a case where the display region is sectioned into a plurality of sectioned regions with a boundary between the pixel columns adjacent to each other,
the pixels arranged in a same sectioned region among the sectioned regions have areas equal to each other, have lengths made equal to each other along a direction orthogonal to an alignment direction of the pixels, and have pitches made equal to each other, and
among the sectioned regions adjacent to each other, a pitch of the pixels arranged in each of the sectioned regions arranged on an inner side is smaller than a pitch of the pixels arranged in each of the sectioned regions arranged on an outer side.

Furthermore, the present disclosure may be, for example, (3) an electronic device including the display device according to (1) described above.

### BRIEF DESCRIPTION OF DRAWINGS

FIG. 1 is a plan view for explaining an implementation example of a display device.

FIG. 2 is a plan view for explaining an implementation example of a pixel column.

FIG. 3A is a plan view for explaining a display device according to a first embodiment. FIG. 3B is a graph for explaining an example of a resolution distribution in a radial direction of the display device illustrated in FIG. 3A.

FIG. 4 is an enlarged plan view illustrating a part of a pixel array of the display device illustrated in FIG. 3A.

FIGS. 5A and 5B are plan views for explaining an arrangement example of sub-pixels of the display device according to the first embodiment.

FIGS. 6A and 6B are plan views for explaining an arrangement example of sub-pixels of the display device according to the first embodiment.

FIGS. 7A and 7B are plan views for explaining an arrangement example of sub-pixels in a modification of the display device according to the first embodiment .

FIGS. 8A and 8B are plan views for explaining an arrangement example of sub-pixels in a modification of the display device according to the first embodiment.

FIG. 9A is a plan view for explaining a display device according to a second embodiment. FIG. 9B is a graph for explaining an example of a resolution distribution in the radial direction of the display device illustrated in FIG. 9A.

FIG. 10 is an enlarged plan view illustrating a part of a pixel array of the display device illustrated in FIG. 9A.

FIG. 11A is a plan view for explaining a display device according to a third embodiment. FIG. 11B is a graph for explaining an example of a resolution distribution in the radial direction of the display device illustrated in FIG. 11A.

FIGS. 12A and 12B are views for explaining an implementation example of an electronic device using the display device.

### MODE FOR CARRYING OUT THE INVENTION

Hereinafter, implementation examples and the like according to the present disclosure will be described with reference to the drawings. Note that the description will be given in the following order. In the description and the drawings, configurations having substantially the same functional configuration are denoted by the same reference numerals, and redundant descriptions are omitted.

Note that the description will be made in the following order.
1. First embodiment
2. Second embodiment
3. Third embodiment
4. Electronic device

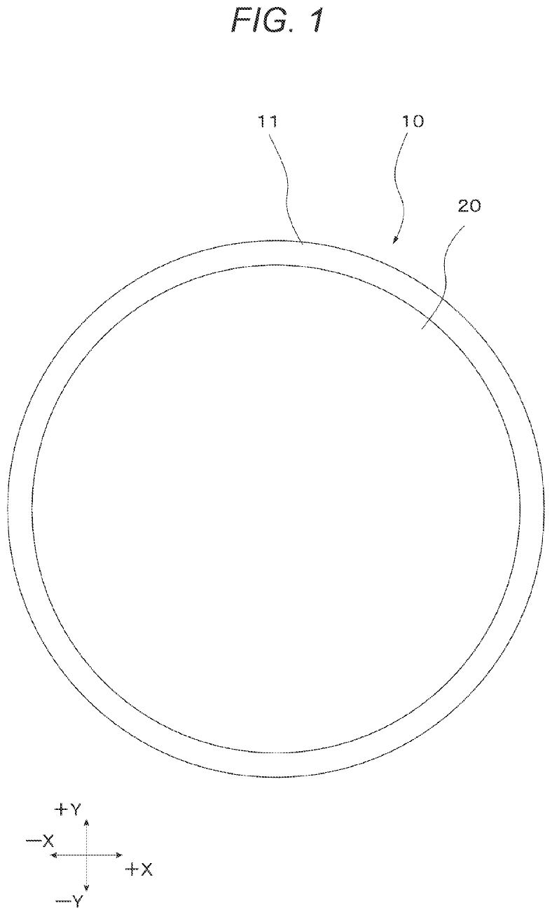

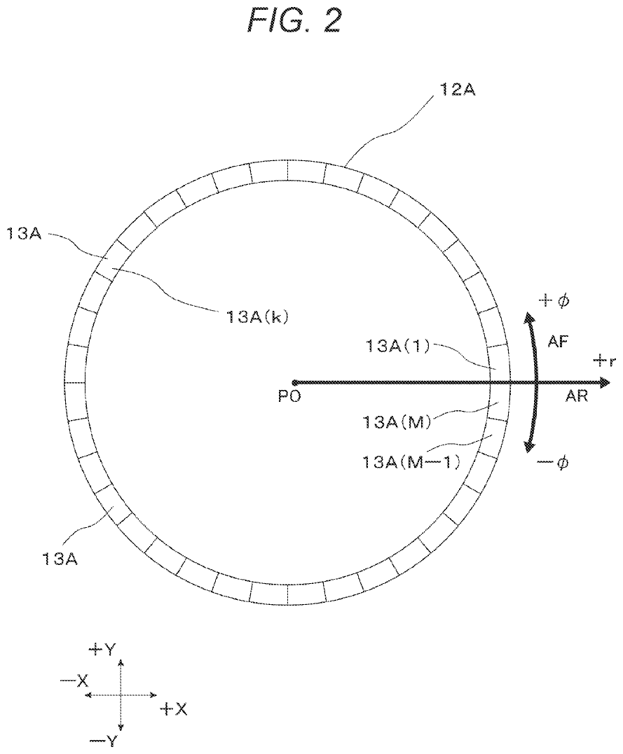

The following description is a preferred specific example of the present disclosure, and the content of the present disclosure is not limited to these embodiments and the like. Furthermore, in the following description, directions of front and back, left and right, up and down, and the like are indicated in consideration of convenience of description, but the content of the present disclosure is not limited to these directions. In the examples of FIGS. 1 and 2, it is assumed that a Y-axis direction is an up-down direction (an upper side is a +Y direction and a lower side is a −Y direction), and an X-axis direction is a left-right direction (a right side is a +X direction, and a left side is in a −X direction), and description will be made on the basis of this. This similarly applies to FIG. 2. A relative magnitude ratio such as a size illustrated in each drawing of FIG. 1 and the like is described for convenience, and does not limit an actual magnitude ratio. This similarly applies to each drawing of FIGS. 2 to 12 regarding the definition and the magnitude ratio regarding these directions.

### 1 First Embodiment

### 1-1 Configuration of Display Device

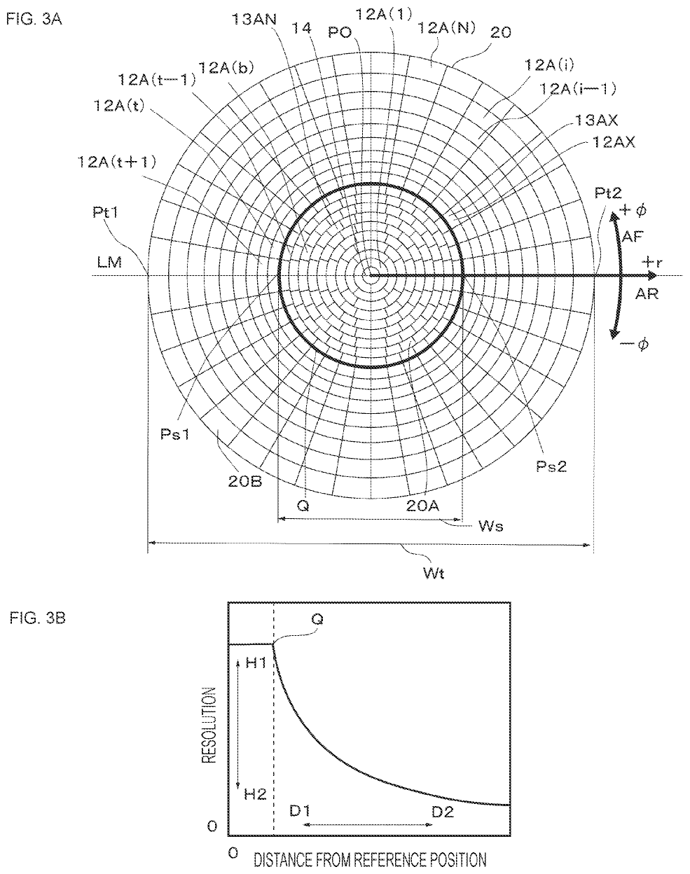

As illustrated in FIGS. 1, 3A, and the like, a display device 10 according to an implementation example of the present disclosure has a display unit 11 and a plurality of pixel columns 12A arranged on the display unit 11. FIG. 1 is a plan view illustrating an implementation example of the display device 10. FIG. 3A is a view illustrating an implementation example of an arrangement pattern of the pixel columns 12A in a display region 20.

The display device 10 is not particularly limited, but may be a microdisplay, an organic EL display device, or the like. Furthermore, the display device 10 may be used for various electronic devices. Examples of the electronic device in which the display device 10 is used include, for example, display devices for VR, mixed reality (MR), augmented reality (AR), or HMD, electronic binoculars, and the like.

### (Display Unit)

The display unit 11 has the display region 20 in which the plurality of pixel columns 12A is arranged. The display region 20 indicates a region where effective display is performed, and is determined to have a shape such as, for example, a circular shape, an elliptical shape, or a polygonal shape in accordance with conditions such as a content of the display device 10 and an arrangement pattern of the pixel columns 12A. In the example of FIG. 1, the display region 20 is formed in a circular shape.

### (Pixel Column)

As illustrated in FIG. 3A, in the display unit 11, a plurality of pixel columns 12A(1), . . . , 12A(i), . . . , 12A(N) is concentrically arranged along a plane direction of the display region 20, around, as a center, a reference position PO (an origin of polar coordinates to be described later) which is a predetermined position in the display region 20. At this time, with the reference position PO as a center, a side closer to the reference position PO is defined as an inner side, a direction radially away from the reference position PO is defined as an outer-side direction, and an inner and outer direction is defined radially from the reference position PO. Furthermore, as illustrated in FIG. 3, in the arrangement of the pixel column 12A, among the pixel column 12A(i−1) and the pixel column 12A(i), the pixel column 12A(i−1) is the pixel column 12A formed on the inner side along the inner and outer direction with respect to the pixel column 12A(i). Here, i and N are positive integers. The pixel column 12A(1) is arranged most proximally from the reference position PO, and the pixel column 12A(i) is arranged i-th in the outer-side direction (a direction away from the reference position PO) from the pixel column 12A(i) arranged most proximal to the reference position PO. The pixel column 12A(N) is arranged most distally from the reference position PO. In this example, N pieces of the pixel column 12A are arranged concentrically around the reference position PO as a center. In the present specification, in a case where the pixel columns 12A(1), . . . , 12A(i), . . . , and 12A(N) are collectively described without being particularly distinguished, the plurality of pixel columns 12A(1), . . . , 12A(i), . . . , and 12A(N) is written as the pixel columns 12A.

In the example of FIG. 3A and the like, the pixel columns 12A are concentrically arranged along a plane direction of the display region 20 with a center of the display region 20 as the reference position PO. Hereinafter, as illustrated in the example of FIG. 3A, a case where the display device 10 has the pixel columns 12A that are concentrically arranged will be described in detail as an example. Note that, in FIG. 3A, an arrow AR indicates a moving radius in a case where a polar coordinate system with the reference position PO as an origin is defined as a display region. The illustrated arrow AR indicates one of radial directions (sometimes referred to as r-axis directions). An arrow AF indicates a deflection angle direction (sometimes referred to as a o axis direction) . The deflection angle direction is determined in a circumferential direction of a circle centered on the reference position PO. In the example of FIG. 2, in the pixel column 12A, an alignment direction of pixels 13A is the deflection angle direction, and the inner and outer direction is the radial direction. Therefore, the alignment direction of the pixels 13A may be referred to as the deflection angle direction, and the inner and outer direction may be referred to as the radial direction. Furthermore, the outer-side direction is the +r direction in FIG. 3, and the inner-side direction is a direction approaching the reference position PO (a direction opposite to the +r direction). The definition regarding the polar coordinates described above is also similar in FIGS. 2 and 4 to 11. Furthermore, as illustrated in FIG. 2, in a case where the pixels 13A are arranged in a circular shape in the pixel column 12A, a direction orthogonal to the alignment direction of the pixels 13A is the radial direction. This similarly applies to FIGS. 3A, 8A, and 10 A.

### (Pixel)

As illustrated in FIG. 2, the pixel column 12A each has a plurality of pixels 13A(1), . . . , 13A(k), . . . , and 13A(M) arranged in a ring shape. k and M are positive integers. FIG. 2 is a plan view illustrating an implementation example of an arrangement pattern of the pixels 13A in the pixel column 12A. In the example of the pixel column 12A in FIG. 2, an alignment direction of the plurality of pixels 13A(1), . . . , 13A(k), . . . , 13A(M) is the deflection angle direction as described above.

The pixel 13A(1) indicates one pixel 13A selected from an array of the pixels 13A in the pixel column 12A. The pixel 13A(k) indicates a k-th pixel arranged in a counterclockwise direction from the pixel 13A(1) along the alignment direction of the pixels 13A (the deflection angle direction (the arrow AF direction)) in the pixel column 12A. The pixel 13A(M) indicates an M-th pixel arranged from the pixel 13A(1) in a counterclockwise direction along the alignment direction of the pixels 13A in the pixel column 12A. The pixel 13A(M) is adjacent to the pixel 13A(M−1) and the pixel 13A(1). The pixel column 12A is formed by arranging M pieces of the pixel 13A in a ring shape. The number of arranged pixels 13A is determined in accordance with the pixel column 12A(i). In the present specification, in a case where the pixels 13A(1) , . . . , 13A(k), . . . , and 13A(M) are collectively described without being particularly distinguished, the pixels 13A(1), . . . , 13A(k), . . . , and 13A(M) are written as the pixels 13A.

Note that the counterclockwise direction and the clockwise direction respectively indicate a counterclockwise direction (the +φ direction in FIG. 2) and a clockwise direction (the −φ direction in FIG. 2), in a rotation direction around the reference position PO as a center in a plane of the display region 20. The counterclockwise direction side and the clockwise direction side described later also indicate the counterclockwise direction side and the clockwise direction side in the direction centered on the reference position.

In each pixel column 12A, the pixel 13A is formed in a partial annular shape. However, the shape of the pixel 13A is not limited thereto, and may be formed in a partially elliptical annular shape, or may be formed in a circular shape, a polygonal shape, or the like. In the example illustrated in FIG. 2, in each pixel column 12A, the pixels 13A different from each other have the same shape. Furthermore, in each pixel column 12A, an area of each pixel 13A is preferably the same from the viewpoint of suppressing a resolution blur in the deflection angle direction of the pixel 13A. Hereinafter, a case where the shape and the area of each pixel 13A are the same in each pixel column 12A will be described as an example.

### (Light Emitting Element)

The pixel 13A has a structure including a light emitting element (not illustrated). Specifically, an organic EL element or the like can be exemplified as the light emitting element. The organic EL element has a structure in which an organic electroluminescence layer (organic EL layer) is provided between two electrodes. The light emitting element is connected to an IC circuit or the like that controls a light emitting state of the light emitting element. As a result, the light emitting state of the light emitting element is controlled.

### (Arrangement of Pixels)

In the display device 10 according to the first embodiment, in a case where the pixel column 12A arranged at a predetermined position in the plurality of pixel columns 12A is defined as a reference pixel column 12AX, and the pixel 13A forming the reference pixel column 12AX is defined as a reference pixel 13AX, the pixels 13A forming pixel column 12A arranged on the outer side of the reference pixel column 12AX have a similar shape obtained by enlarging a shape of the reference pixel 13AX.

(Pixel on Outer Side from Reference Pixel Column)

As illustrated in FIG. 3A, in a case where a pixel column 12A(t) (t is a predetermined positive integer of 2 or more and N−1 or less), which is disposed t-th toward the outer side from a pixel column 12A(1), is defined as the reference pixel column 12AX, a shape of each pixel 13A constituting each of the pixel columns 12A from the pixel column 12A(t+1) to the pixel column 12A(N) is a similar shape obtained by enlarging a shape of the reference pixel 13AX of the reference pixel column 12AX. At this time, the pixel 13A in an adjacent pixel column 12A(j) and the pixel 13A in an adjacent pixel column 12A(j+1) are also the same as or similar to each other.

### (Similarity Ratio)

A similarity ratio of the pixels 13A forming the pixel column 12A arranged on the outer side of the reference pixel column 12AX is preferably as follows. That is, among adjacent pixel columns 12A(j) and 12A(j+1) (j is a positive integer of t+1 or more and N−1 or less) arranged on the outer side of the reference pixel column 12AX, a ratio of a size of the pixel 13A forming the pixel column 12A(j+1) on the outer side to a size of the pixel 13A forming the pixel column 12A(j) on the inner side is defined as a similarity ratio SJ. A size ratio of the pixel 13A forming the pixel column 12A(t+1) adjacent to the reference pixel column 12AX on the outer side of the reference pixel column 12AX (the pixel column 12A(t)) to a size of the reference pixel 13AX is defined as a similarity ratio SA. At this time, the similarity ratio SJ and the similarity ratio SA coincide with each other.

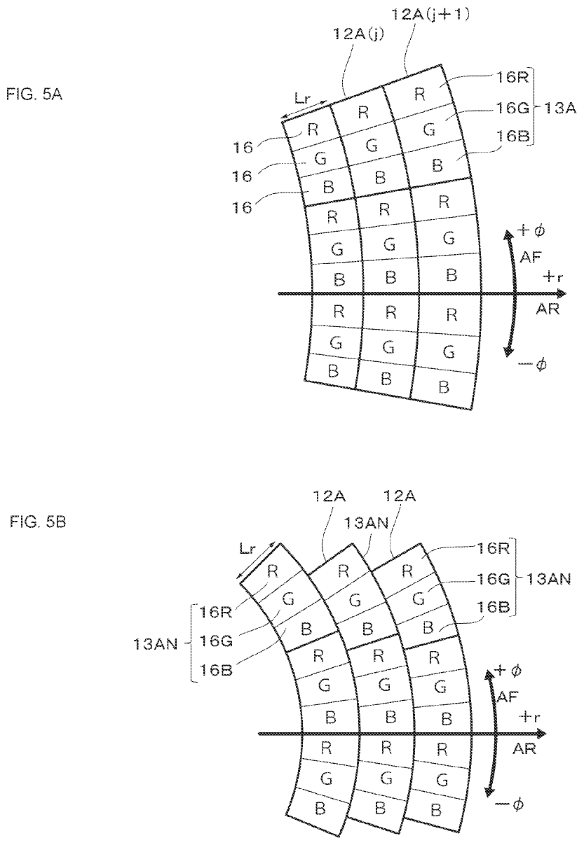

Note that the similarity ratio SJ is determined by Lr(j+1)/Lr(j). Lr(j+1)/Lr(j) is a ratio of a dimension in the radial direction (a length Lr(j+1)) of the pixel 13A forming the pixel column 12A(j+1) with respect to a dimension in the radial direction (a length Lr(j)) of the pixel 13A forming the pixel column 12A(j). Note that, as illustrated in FIG. 5, the dimension in the radial direction of the pixel 13A(j) is described as the length Lr(j), but the dimension in the radial direction may be simply described as the length Lr for convenience of description in a case where the pixel 13A(j) is not limited, for example.

The similarity ratio SA is determined by Lr(t+1)/Lr(t). Lr(t+1)/Lr(t) is a ratio of a dimension in the radial direction (a length Lr (t+1)) of the pixel 13A forming the pixel column 12A(t+1) with respect to a dimension in the radial direction (a length Lr(t)) of the pixels 13A (the reference pixels 13AX) forming the pixel column 12A(t) corresponding to the reference pixel column 12AX.

In this case, when the similarity ratio SA=R (R is a predetermined positive value exceeding 1), Lr(j+1)/Lr(j)=Lr(t+1)/Lr(t)=R is satisfied in a case where j is a positive integer of t+1 or more and N−1 or less. That is, the similarity ratio between adjacent pixel columns 12A is constant on the outer side of the reference pixel column 12AX.

(Number of Pixels in Pixel Column on Outer Side from Reference Pixel Column)

In the example of FIG. 3A, the number of pixels 13A arranged in each pixel column 12A(j) on the outer side from the reference pixel column 12AX coincides with the number of reference pixels 13AX arranged in the reference pixel column 12AX. Furthermore, the pixels 13A forming the pixel column 12A on the outer side from the reference pixel column 12AX are radially aligned at positions on the outer side from the reference position PO along the radial direction, with respect to a position of the reference pixel 13AX. The outer side from the reference pixel column 12AX indicates a region on the outer side from an outer boundary, in a case where the outer boundary is between the pixel column 12A(t) to be the reference pixel column 12AX and the pixel column 12A(t+1) adjacent thereto.

In this example, in the pixel column 12A(j+1), the number of arranged pixels 13A is made constant with respect to the pixel column 12A(j), and the size of the individual pixels 13A is enlarged at the constant similarity ratio R. At this time, as the pixel column 12A(j) is arranged further on the outer side (as the value of j increases), the pixel column 12A(j) is formed with a large pixel 13A, and a pitch (Pr, Pf) of the pixel 13A is widened, and a state with a lower resolution can be easily achieved as the pixel column 12A(j) is closer to the outer side in the display region 20.

### (Pitch of Pixels)

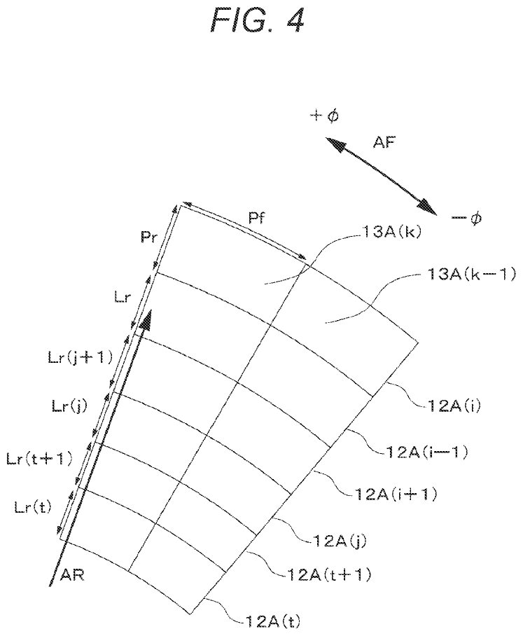

In a case where the pixel columns 12A are arranged concentrically as illustrated in the example of FIG. 3A, a pitch of the pixels 13A is determined by the pitch Pr in the radial direction and the pitch Pf in the deflection angle direction. In the example of FIG. 3A, a pitch Pr(i) in the radial direction of the pixels 13A at a position of the pixel column 12A(i) (i is a positive integer of 1 or more and N or less) is, as illustrated in FIG. 4, determined as a distance along the radial direction from an outer end of the pixel 13A forming one pixel column 12A(i) among adjacent pixel columns 12A(i−1) and 12A(i) to an outer end of a pixel 13A (a pixel 13A forming the pixel column 12A(i−1)) adjacent to the pixel 13A in the radial direction. In the example of FIG. 3A, the pitch Pr in the radial direction is the length Lr of one pixel 13A along the radial direction of the pixel 13A as illustrated in FIG. 4.

The pitch Pf(i) in the deflection angle direction of the pixels 13A at the position of the pixel column 12A(i) is, as illustrated in FIG. 4, defined as a distance (an arc length) along the deflection angle direction from an end (an outer end on the +φ direction side) of the pixel 13A(k−1) to an end (an outer end on the +φ direction side) of the pixel 13A(k) among the adjacent pixels 13A(k−1) and 13A(k) (k is a positive integer of 2 or more and M or less) (the adjacent pixel 13A(1) and 13A(M) at the position of the pixel 13A(1)) among the pixels 13A forming the pixel column 12A(i).

From the viewpoint of a balance between a resolution in the radial direction (PPIr) and a resolution in the deflection angle direction (PPIf), the pitch Pr in the radial direction and the pitch Pf in the deflection angle direction of the pixels 13A are preferably equal to each other.

### (Resolution)

In a case where the pixel columns 12A are arranged concentrically as in the example of FIG. 3A, a resolution of the display region 20 is determined by a resolution in the radial direction (PPIr) and a resolution in the deflection angle direction (PPIf). The resolution (PPIr) in the radial direction is defined by the number of pixels 13A included per one inch in length in the radial direction. In the display region 20, the resolution PPIr is determined by PPIr=1/Pr using the pitch Pr. PPIr(i) at a position of the pixel column 12A(i) (i is a positive integer of 1 or more and N or less) is determined by PPIr(i)=1/Pr(i) on the basis of the pitch Pr(i) in the radial direction of the pixels 13A at a position of the pixel column 12A(i).

The resolution (PPIf) in the deflection angle direction is defined by the number of pixels 13A included per one inch in length in the radial direction. In the display region 20, the resolution PPIf is determined by PPIf=1/Pf using the pitch Pf. PPIf(i) at a position of the pixel column 12A(i) (i is a positive integer of 1 or more and N or less) is determined by PPIf(i)=1/Pf(i) on the basis of the pitch Pf(i) in the radial direction of the pixels 13A at a position of the pixel column 12A(i).

In a case where the display device 10 is formed by larger pixels 13A as the pixel column 12A(i) is arranged further on the outer side, the lengths Lr(i) and Lf(i) also increase and the pitches Pr(i) and Pf(i) also increase, so that the resolutions PPIr(i) and PPIf(i) decrease at a position of the pixel column 12A arranged further on the outer side.

(Pixel on Inner Side from Reference Pixel Column)

In the display device 10, as illustrated in FIG. 3A, the pixels 13A (inner pixels 13AN) arranged on the inner side of the reference pixel column 12AX (the pixel column 12A(t)) have areas equal to each other. Moreover, the inner pixels 13AN have lengths made equal to each other along a direction orthogonal to an alignment direction of the pixels 13A in each pixel column 12A(b) (b is a positive integer t−1 or less). In the example of FIG. 3A, the lengths Lr of the inner pixels 13AN along the radial direction are made equal to each other. Note that the inner pixel 13AN indicates the pixel 13A arranged on the inner side of the reference pixel column 12AX, that is, indicates the pixel 13A forming the pixel column 12A from the pixel column 12A(1) to the pixel column 12A(t−1).

Here, the inner side from the reference pixel column 12AX indicates the inner side from a boundary Q defined between the pixel column 12A(t) to be the reference pixel column 12AX and the pixel column 12A(t−1) adjacent thereto in the display region 20. Note that, in a case where the display region 20 is sectioned by the boundary Q, a region located closer to the reference position PO may be referred to as a first portion 20A, and a portion located on the outer side of the first portion 20A may be referred to as a second portion 20B. In this case, the inner side from the reference pixel column 12AX indicates the first portion 20A.

An area for one inner pixel 13AN and the number of pixels in each pixel column 12A(b) are determined such that, as illustrated in FIG. 3B, a resolution at a position on the inner side from the reference pixel column 12AX (a position in the first portion 20A) is higher than a resolution in the second portion 20B. Furthermore, the number of pixels in each pixel column 12A(b) is determined such that an area for one inner pixel 13AN is constant, that is, areas of the pixels 13A included in the pixel column 12A from the pixel column 12A(1) to the pixel column 12A(t−1) are the same as each other.

Furthermore, the pixels 13A (the inner pixels 13AN) arranged on the inner side of the reference pixel column 12AX (the pixel column 12A(t)) have equal pitches. In the example of FIG. 3A, a position of each pixel column 12A with respect to the reference position PO and an area, arrangement, and the like of each pixel 13A in each pixel column 12A are determined such that the pitch Pr in the radial direction of the inner pixel 13AN is constant, and the pitch Pf in the deflection angle direction of the inner pixel 13AN is constant. The pitch Pr in the radial direction and the pitch Pf in the deflection angle direction of the inner pixel 13AN are determined such that a resolution in the radial direction and a resolution in the deflection angle direction on the inner side of the reference pixel column 12AX are respectively equal to or higher than a resolution in the radial direction and equal to or higher than a resolution in the deflection angle direction in the reference pixel column 12AX.

### (Central Pixel)

Note that, in the display region 20, in a case where there is a space further on the inner side of the pixel column 12A(1), pixels may be arranged or arrangement of pixels may be avoided further on the inner side of the pixel column 12A(1). In the example of FIG. 3A, a pixel (in FIG. 3A, a central pixel 14) is arranged further on the inner side of the pixel column 12A(1).

### (Resolution Distribution)

In the display device 10, for the resolution (PPIr) in the radial direction in the display region 20, a resolution distribution in the radial direction in the display region 20 is determined by specifying a resolution of the resolution PPIr(i) in the radial direction for each pixel column 12A. In the display device 10 exemplified in FIG. 3A, as illustrated in FIG. 3B, the resolution (PPIr) in the radial direction on the inner side from a position of the reference pixel column 12AX (the pixel column 12A(t)) in the display region 20 is approximately constant, and larger than the resolution (PPIr) in the radial direction in the reference pixel column 12AX. This configuration can be realized by adjusting a pitch, an area for one inner pixel 13AN, and the number of pixels 13A arranged in each pixel column 12A for the inner pixel 13AN.

Furthermore, at the position of the pixel column 12A on the outer side of the boundary Q with a boundary between the pixel column 12A(t−1) and the pixel column 12A(t) as the boundary Q, the resolution PPIr decreases as the position is farther from the reference position PO.

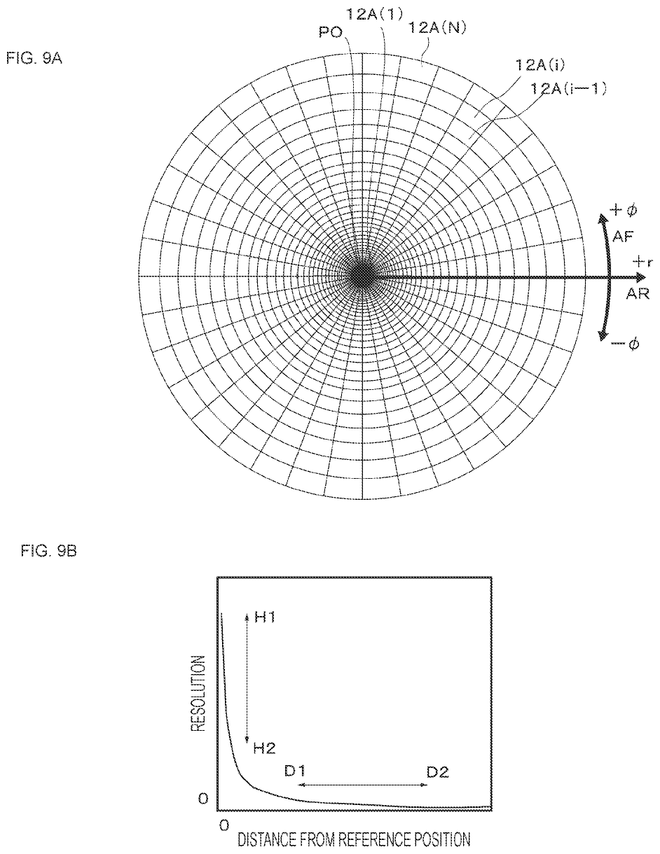

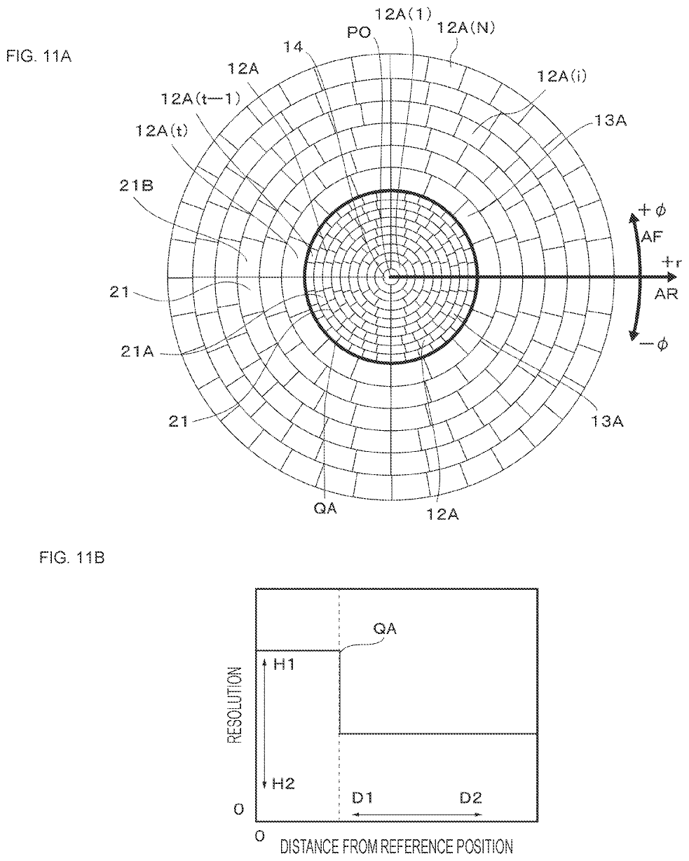

Note that, FIG. 3B illustrates an example of a resolution distribution in the radial direction of the display region 20 in the display device 10 in FIG. 3A. In a graph of the resolution distribution of FIG. 3B, a horizontal axis indicates a distance from a reference position along the radial direction with the reference position PO as an origin. A vertical axis represents a resolution (pixels/inch). In FIG. 3B, an arrow H1 direction indicates a direction in which the resolution is high, and an arrow H2 direction indicates a direction in which the resolution is low. Furthermore, in FIG. 3B, an arrow D1 direction indicates a direction in which a distance from the reference position becomes shorter, and an arrow D1 direction indicates a direction in which a distance from the reference position becomes longer. This point is the same for FIGS. 9B and 11B. Furthermore, in FIG. 3B, a broken line indicates a case where a distance (a distance in the +r direction) from the reference position along the radial direction is the boundary Q between the first portion 20A and the second portion 20B to be described later. A region closer to the reference position PO from the boundary Q (in FIG. 3B, on the arrow D1 side) indicates a resolution of the first portion 20A, and a region having a longer distance from the boundary Q to the reference position PO (in FIG. 3B, on the arrow D2 side) indicates a resolution of the second portion 20B.

Regarding the resolution distribution in the deflection angle direction in the display region 20, the resolution distribution in the deflection angle direction in the display region 20 is determined by specifying the resolution in the deflection angle direction for the position of each pixel column 12A(i). In the example of FIG. 3A, the resolution distribution in the deflection angle direction in the display region 20 is a distribution similar to that of the example of the resolution distribution in the radial direction illustrated in FIG. 3B.

### (Position of Reference Pixel Column)

In the display region 20, the reference pixel column 12AX is a position defining a high-resolution portion (the first portion 20A) in the display region 20 as illustrated in FIG. 3B, that is, a position that determines the boundary Q sectioning the display region 20 into a high-resolution portion (the first portion 20A) and a low-resolution portion (the second portion 20B). The boundary Q between the first portion 20A and the second portion 20B can be specifically defined as the boundary Q (an inner boundary) between the reference pixel column 12AX (the pixel column 12A(t)) and the pixel column 12A(t−1) adjacent to the reference pixel column 12AX on the inner side.

In the display device 10, a predetermined pixel column 12A is preferably determined as the reference pixel column 12AX such that the first portion 20A in the display region 20 satisfies the following range. That is, in a case where a straight line LM passing through the reference position PO and along the radial direction is assumed, a position where the boundary Q between the first portion 20A and the second portion 20B intersects the straight line LM is defined as a position Ps1 and a position Ps2, and a separation distance between the position Ps1 and the position Ps2 is defined as Ws. Furthermore, a position where an outer edge end of the display region 20 intersects the straight line LM is defined as a position Pt1 and a position Pt2, and a separation distance between the position Pt1 and the position Pt2 is defined as Wt. At this time, the predetermined pixel column 12A is preferably defined as the reference pixel column 12AX such that a ratio (Ws/Wt) is 0.05 or more and 0.5 or less.

Considering that human visual acuity is generally strong near the fovea and that the fovea moves due to movement of the eyeball, a region that is easily perceived by a human through vision in a total visual field of a human is defined as a region (a center region) that falls within a circle of a predetermined viewing angle range. In the display device 10, when the ratio (Ws/Wt) is 0.05 or more, the center region that is easily perceived by human vision is easily accommodated in the first portion 20A. Furthermore, when the ratio (Ws/Wt) is 0.5 or less, in the display device 10, a region (a peripheral region) that easily deviates from a region easily perceived by human vision is easily accommodated in the second portion 20B, and it is possible to more efficiently achieve the effect of suppressing the number of pixels 13A in a portion that performs display corresponding to the peripheral region.

### (Sub-Pixel)

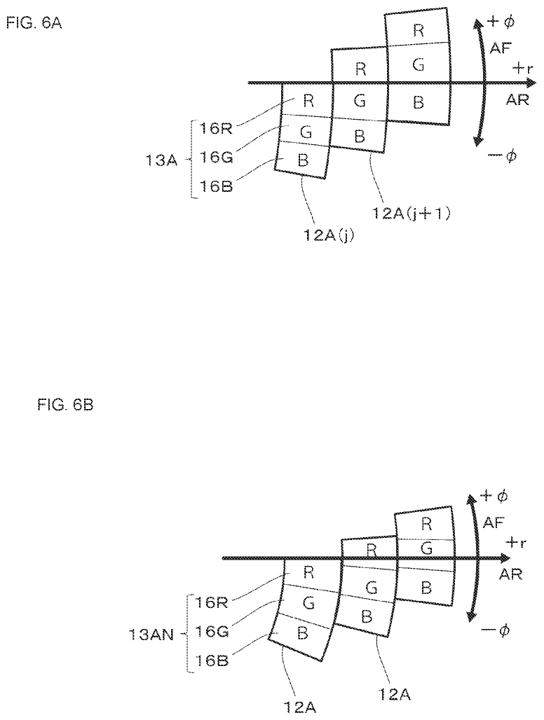

In the display device 10, as illustrated in FIGS. 5A and 5B, the pixel 13A may have a plurality of sub-pixels 16. Here, a case will be described as an example in which three colors of red, green, and blue are defined as a plurality of color types of the sub-pixels 16 forming one pixel 13A. FIG. 5A is a view illustrating an implementation example of an arrangement pattern of the sub-pixels 16 in the second portion 20B. FIG. 5B is a view illustrating an implementation example of an arrangement pattern of the sub-pixels 16 in the first portion 20A. Note that, in FIGS. 5A and 5B, characters R, G, and B described in a region of individual sub-pixels 16 indicate red, green, and blue, respectively, and the sub-pixels 16 denoted with R, G, and B indicate a red sub-pixel 16R, a green sub-pixel 16G, and a blue sub-pixel 16B, respectively. This point similarly applies to FIGS. 6A, 6B, 7A, 7B, 8A, and 8B. Note that, in a case where the red sub-pixel 16R, the green sub-pixel 16G, and the blue sub-pixel 16B are not particularly distinguished, the red sub-pixel 16R, the green sub-pixel 16G, and the blue sub-pixel 16B may be collectively referred to as the sub-pixels 16.

In the display device 10, the arrangement patterns of the color types of the sub-pixels 16 in the individual pixels 13A are the same as each other. In the example of FIG. 5A, for any pixel 13A(k) (k is a positive integer of 1 or more and M or less), a plurality of sub-pixels 16 is aligned for one pixel 13A along the deflection angle direction. In this example, the sub-pixels 16 are arranged in the order of the blue sub-pixel 16B, the green sub-pixel 16G, and the red sub-pixel 16R from the −φ direction side toward the +φ direction side. This arrangement pattern is similar in FIGS. 5A and 5B. Note that each color type of the red, green, and blue colors can be defined as light having a dominant wavelength in a range of, for example, 610 nm to 650 nm, a range of 510 nm to 590 nm, and a wavelength range of 440 nm to 480 nm, respectively.

### (Sub-Pixel Arranged on Outer Side of Reference Pixel Column)

In the display device 10, for every color type of the sub-pixel 16, the sub-pixel 16 arranged on the outer side of the reference pixel column 12AX has a similar shape obtained by enlarging a shape of the sub-pixel 16 forming the reference pixel 13AX.

For example, for the red sub-pixel 16R, a shape of the red sub-pixel 16R constituting each pixel column 12A from the pixel column 12A(t+1) to the pixel column 12A(N) arranged on the outer side of the reference pixel column 12AX (the pixel column 12A(t)) is a similar shape obtained by enlarging a shape of the red sub-pixel 16R forming the reference pixel 13AX. The green sub-pixel 16G and the blue sub-pixel 16B are also similar to the red sub-pixel 16R. Shapes of the green sub-pixel 16G and the blue sub-pixel 16B constituting each pixel column 12A from the pixel column 12A(t+1) to the pixel column 12A(N) are similar shapes obtained by enlarging shapes of the green sub-pixel 16G and the blue sub-pixel 16B forming the respective reference pixels 13AX.

### (Similarity Ratio for Sub-Pixel)

Furthermore, it is preferable that the similarity ratio SdJ and the reference similarity ratio SdA coincide with each other for every color type of the sub-pixel 16. The similarity ratio SdJ is a similarity ratio of a size of the sub-pixel 16 forming the pixel column 12A(j+1) on the outer side to a size of the sub-pixel 16 forming the pixel column 12A(j) on the inner side, among the adjacent pixel columns 12A(j) and 12A(j+1) (j is a positive integer of t+1 or more and N−1 or less) arranged on the outer side of the reference pixel column 12AX.

The reference similarity ratio SdA indicates a similarity ratio of a size of the sub-pixel 16 forming the pixel 13A in the pixel column 12A(t+1) to a size of the sub-pixel 16 forming the reference pixel 13AX in the reference pixel column 12AX (the pixel column 12A(t)). Note that the pixel column 12A(t+1) is the pixel column 12A adjacent to the reference pixel column 12AX on the outer side of the reference pixel column 12AX.

The similarity ratio SdJ and the reference similarity ratio SdA are determined for every type of the sub-pixel 16. Hereinafter, the similarity ratio SdJ and the reference similarity ratio SdA for the red sub-pixel 16R are defined as a similarity ratio SdJ(R) and a reference similarity ratio SdA(R), the similarity ratio SdJ and the reference similarity ratio SdA for the green sub-pixel 16G are defined as a similarity ratio SdJ(G) and a reference similarity ratio SdA(G), and the similarity ratio SdJ and the reference similarity ratio SdA of the blue sub-pixel 16B are defined as a similarity ratio SdJ(B) and a reference similarity ratio SdA(B).

In the example of FIG. 5A, in the pixel column 12A arranged on the outer side of the reference pixel column 12AX (the pixel column 12A(t)), the similarity ratio SdJ(R) coincides with the reference similarity ratio SdA(R), the similarity ratio SdJ(G) coincides with the reference similarity ratio SdA(G), and the similarity ratio SdJ(B) coincides with the reference similarity ratio SdA(B).

Note that, similarly to the similarity ratio for the pixel 13A, the similarity ratio SdJ and the reference similarity ratio SdA for the red sub-pixel 16R are dimensional ratios in the radial direction for the red sub-pixel 16R. This point similarly applies to the green sub-pixel 16G and the blue sub-pixel 16B.

### (Reference Similarity Ratio in Sub-Pixel)

In the display device 10, the reference similarity ratios SdA coincides between the sub-pixels 16 of different color types. In the example of FIG. 5A, the reference similarity ratio SdA(R), the reference similarity ratio SdA(G), and the reference similarity ratio SdA(B) coincide with each other.

In the display device 10, for every color type of the sub-pixel 16, the sub-pixel 16 arranged on the outer side of the reference pixel column 12AX has a similar shape obtained by enlarging a shape of the sub-pixel 16 forming the reference pixel 13AX. As a result, even in a case where the pixel 13A has the sub-pixel 16, a resolution distribution of the second portion 20B can be set to the resolution distribution as illustrated in FIG. 3B.

### Sub-Pixel Arranged on Inner Side of Reference Pixel Column

In the display device 10, in a case where the inner pixel 13AN has the sub-pixels 16, the sub-pixels 16 forming the inner pixel 13AN have areas equal to each other for every sub-pixel 16. Furthermore, lengths along a direction orthogonal to an alignment direction of the pixels 13A in each pixel column 12A are made equal to each other for every sub-pixel 16.

For example, for the red sub-pixel 16R, as illustrated in FIG. 5B, the red sub-pixels 16R forming the inner pixel 13AN have areas equal to each other. Moreover, the red sub-pixels 16R forming the inner pixel 13AN have the lengths Lr made equal to each other along the radial direction. These points similarly apply to the green sub-pixel 16R and the blue sub-pixel 16B.

In such a display device 10, even in a case where the pixel 13A has the sub-pixel 16, a resolution distribution on the inner side (the first portion 20A) of the reference pixel column 12AX can be set to the resolution distribution as illustrated in FIG. 3B.

### 1-2 Action and Effect

In the display device 10 according to the first embodiment, the pixel columns 12A are concentrically arranged around, as a center, the reference position PO in the display region 20 as a center. Furthermore, with the boundary Q defined between the reference pixel column 12AX and the pixel column 12A(t−1) adjacent to the reference pixel column 12AX on the inner side, a region on the inner side from the boundary Q is defined as the first portion 20A with the resolution set to be a high resolution, while a region on the outer side from the boundary Q is defined as the second portion 20B with the resolution set to be a low resolution. Therefore, according to the first embodiment, a region (a center region) that is easily perceived through human vision and a region (a peripheral region) on the outer side thereof are easily matched with the first portion 20A and the second portion 20B, respectively. Further, high-resolution display can be achieved for the center region, and an amount of processed data can be reduced by performing low-resolution display for the peripheral region.

In the display device 10, it is possible to suppress complication of an internal structure of the display device in that high-resolution display is realized in the center region by the arrangement of the pixels 13A in the display region 20, and an amount of processed data is reduced by performing low-resolution display for the outer region. This effect is similar for display devices according to second and third embodiments described later.

### 1-3 Modification

### (Modification 1)

In the above description of the display device 10 according to the first embodiment, as illustrated in FIG. 5A, a case has been described as an example in which the individual pixels 13A located on the outer side of the reference pixel column 12AX are radially aligned in the inner and outer direction (the radial direction), but the display device 10 according to the first embodiment is not limited to this example.

### (Pixels Forming Pixel Column Located on Outer Side of Reference Pixel Column)

In the display device 10, as illustrated in FIG. 6A, the pixels 13A in the pixel column 12A located on the outer side of the reference pixel column 12AX may be arranged at positions avoiding positions to be radially aligned in the inner and outer direction (the radial direction). FIG. 6A is a view illustrating an example of a modification of a position of the pixel 13A.

In the example of FIG. 6A, the pixel 13A has the sub-pixels 16 of a plurality of color types. In the example of FIG. 6A, the color types of the sub-pixels 16 are red, green, and blue. Furthermore, arrangement patterns of the color types of the sub-pixels 16 in each pixel 13A are the same as each other. The sub-pixels 16 are aligned along an alignment direction of the pixels (the deflection angle direction in the example of FIG. 6A).

In Modification 1 of the first embodiment, among the adjacent pixel columns 12A(j) and 12A(j+1) arranged on the outer side of the reference pixel column 12AX, for every color type of the sub-pixel 16, the sub-pixel 16 forming one pixel column 12A(j) is preferably arranged at a position avoiding a position to be aligned with a position of the sub-pixel 16 forming another pixel column 12A(j+1) in the inner and outer direction.

In the example of FIG. 6A, for the red sub-pixel 16R, the red sub-pixel 16R forming one pixel column 12A(j) is arranged at a position shifted in the deflection angle direction from a position aligned in the radial direction (an arrow AR direction) with respect to a position of the red sub-pixel 16R forming another pixel column 12A(j+1). As described above, the red sub-pixels 16R are arranged at positions mutually avoiding positions aligned in the radial direction. Similarly to the red sub-pixel 16R, the green sub-pixel 16G and the blue sub-pixel 16B are also arranged at positions mutually avoiding positions aligned in the radial direction.

Note that, in the example of FIG. 6A, a position in the deflection angle direction of the red sub-pixel 16R forming the pixel column 12A(j+1) is shifted in the +φ direction by a distance corresponding to one sub-pixel 16, with respect to a position in the deflection angle direction of the red sub-pixel 16R forming the pixel column 12A(j). Similarly to the red sub-pixel 16R, the green sub-pixel 16G and the blue sub-pixel 16B are also shifted in the to direction by a distance corresponding to one sub-pixel 16.

### (Pixels Forming Pixel Column Located on Inner Side of Reference Pixel Column)

In Modification 1 of the first embodiment, as illustrated in FIG. 6B, in a case where the pixel 13A has the sub-pixels 16 of a plurality of color types, among the adjacent pixel columns 12A and 12A arranged on the inner side of the reference pixel column 12AX, for every color type of the sub-pixels 16, the sub-pixel 16 forming one pixel column 12A is preferably arranged at a position avoiding a position to be aligned with a position of the sub-pixel 16 forming another pixel column 12A in the inner and outer direction.

For example, for the red sub-pixel 16R, the red sub-pixel 16R forming one pixel column 12A among the pixel columns 12A and 12A adjacent to each other on the inner side of the reference pixel column 12AX is arranged at a position shifted in the deflection angle direction with respect to a position aligned in the radial direction, with respect to a position of the red sub-pixel 16R forming another pixel column 12A. The green sub-pixel 16G and the green sub-pixel 16B are also similar to the red sub-pixel 16R.

### (Action and Effect)

In the display device 10 according to Modification 1, it is possible to avoid a state in which the color types of the sub-pixels 16 are aligned in the inner and outer direction in the adjacent pixel columns 12A, and an occurrence of a pseudo contour in the display region 20 can be more effectively suppressed.

### (Modification 2)

In the above description of the display device 10 according to the first embodiment, a case has been described as an example in which the arrangement pattern of the sub-pixels 16 is a pattern in which the sub-pixels 16 are arranged in a line along an alignment direction of the pixels 13A. However, in the display device 10 according to the first embodiment, the example of the arrangement pattern of the sub-pixels 16 is not limited to this example.

The arrangement pattern of the sub-pixels 16 may be the following pattern. For one pixel 13A, a plurality of sub-pixels 16 may be arranged in each direction among the alignment direction of the pixels 13A forming the pixel column 12A and a direction orthogonal to the alignment direction.

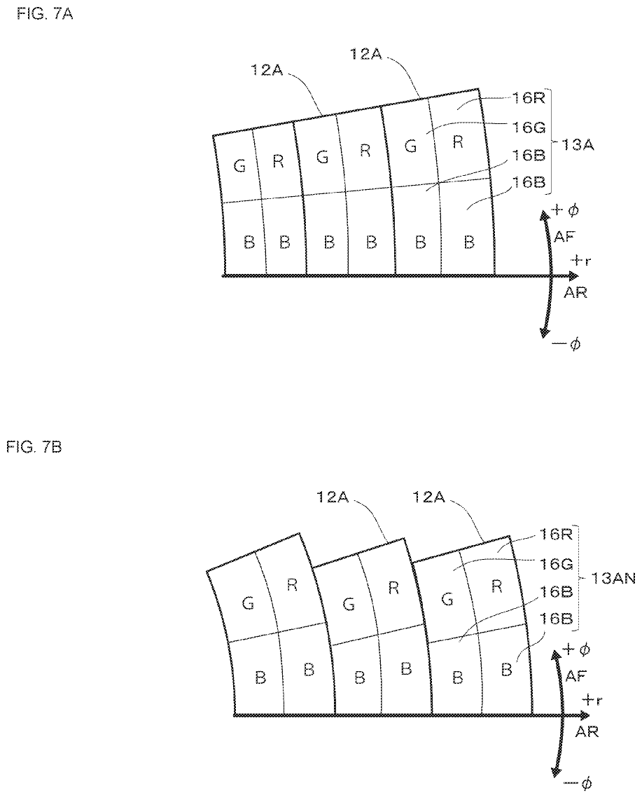

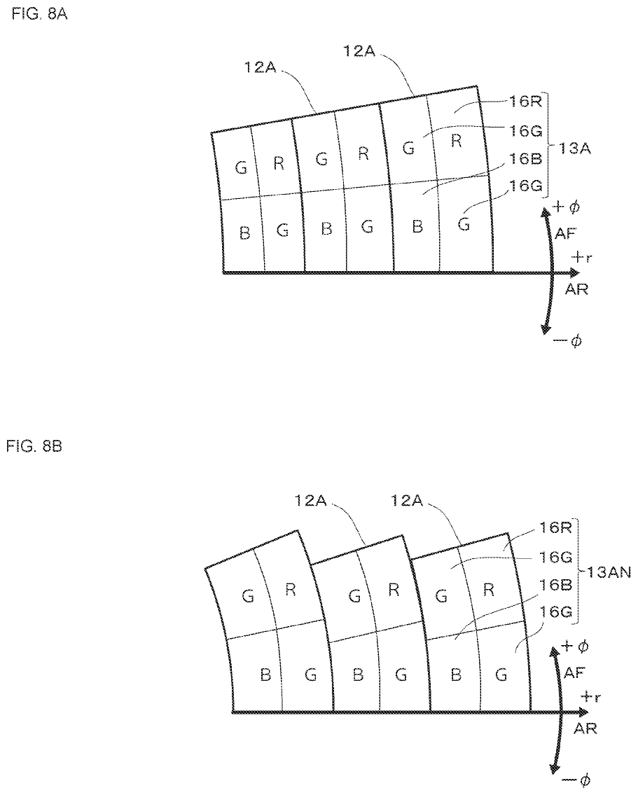

In the example of FIGS. 7A and 7B, in one pixel 13A, two sub-pixels 16 are arranged in the deflection angle direction that is the alignment direction of the pixels 13A, and two sub-pixels are arranged in the radial direction that is the direction orthogonal to the alignment direction. In the example of FIGS. 7A and 7B, two blue sub-pixels 16B are arranged on the −φ direction side in one pixel 13A. On the +φ direction side, the green sub-pixel 16G is arranged at a position close to the reference position PO, and the red sub-pixel 16R is arranged at a position far from the reference position PO (+r direction side). FIG. 7A illustrates an example of an arrangement pattern of the sub-pixels 16 in the second portion 20B. Similarly, FIG. 8A to be described later illustrates an example of an arrangement pattern of the sub-pixels 16 in the second portion 20B. FIG. 7B illustrates an example of an arrangement pattern of the sub-pixels 16 in the first portion 20A. Similarly, FIG. 8B described later illustrates an example of the arrangement pattern of the sub-pixels 16 in the first portion 20A.

In the example of FIGS. 8A and 8B, in one pixel 13A, on the −φ direction side, the blue sub-pixel 16B is arranged at a position close to the reference position PO, and the green sub-pixel 16G is arranged at a position far from the reference position PO. On the +φ direction side, the green sub-pixel 16G is arranged at a position close to the reference position PO, and the red sub-pixel 16R is arranged at a position far from the reference position PO.

In the display device 10 according to Modification 2, in a case where the color types of the sub-pixel 16 are red, green, and blue, green and blue can be increased.

### (Modification 3)

In the display device 10 according to the first embodiment, the plurality of pixel columns 12A has been arranged concentrically. The present disclosure is not limited thereto, and the plurality of pixel columns 12A may be arranged in a non-concentric shape such as a concentric elliptical shape or a concentric polygonal shape.

### 2 Second Embodiment

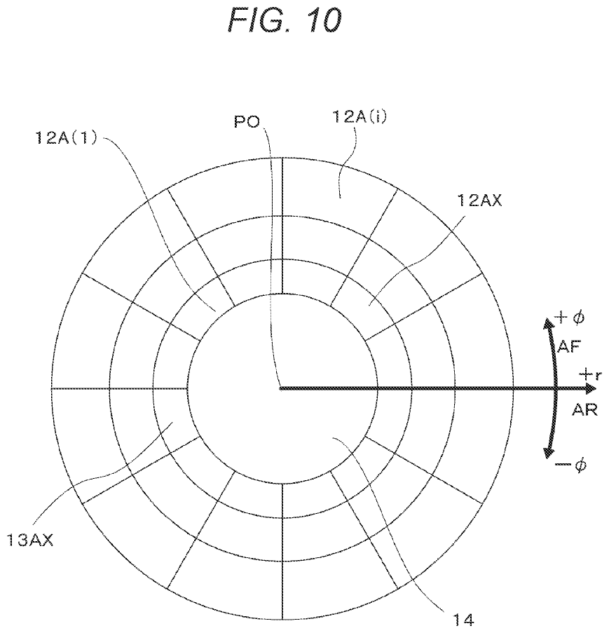

In the first embodiment described above, the reference pixel column 12AX is determined from the pixel columns 12A arranged on the outer side from the pixel column 12A(1) arranged at a position closest to the reference position PO. However, in the display device 10 according to the first embodiment, as illustrated in FIGS. 9A and 10, a pixel column 12A(1) arranged at a position closest to a reference position PO may be determined as a reference pixel column 12AX (the second embodiment). FIG. 9A is a plan view for explaining one of implementation examples of a display device 10 according to the second embodiment. FIG. 10 is an enlarged view for explaining a periphery of the reference position PO of the display device 10 in FIG. 9A.

### 2-1 Configuration of Display Device

In the display device 10 according to the second embodiment, the pixel column 12A(1) is determined as the reference pixel column 12AX. The pixel column 12A(j) on the outer side of the reference pixel column 12AX is similar to that of the first embodiment. Therefore, as illustrated in FIG. 9A, from the pixel column 12A(1) to the pixel column 12A(N), a pixel column 12A having a longer distance from the reference position PO has a larger size of a pixel 13A. Furthermore, in the example illustrated in FIG. 9A, from the pixel column 12A(1) to the pixel column 12A(N), the pixels 13A are arranged at positions radially aligned along the radial direction around the reference position PO as a center. However, this point does not prohibit that the pixels 13A are arranged so as to avoid positions to be radially aligned along the radial direction.

In the second embodiment, unlike the first embodiment, the arrangement of the pixel column 12A is avoided on the inner side of the reference pixel column 12AX. However, in the display device 10 according to the second embodiment, as illustrated in FIG. 10, the central pixel 14 may be arranged further on the inner side of the pixel column 12A(1) serving as the reference pixel column 12AX, similarly to the first embodiment.

### (Resolution Distribution)

In the display device 10 according to the second embodiment, similarly to the first embodiment, a resolution distribution for a resolution (PPIr) in the radial direction and a resolution (PPIf) in the deflection angle direction in the display region 20 is determined. As illustrated in FIG. 9B, similarly to the resolution distribution in the radial direction of the second portion 20B in the display device 10 according to the first embodiment, in the resolution (PPIr) in the radial direction in the display region 20 of the display device 10, a resolution rate is high (in FIG. 9B, an arrow H1 side) in the vicinity of the reference position PO (an arrow D1 side in FIG. 9B), and the resolution decreases (in FIG. 9B, an arrow H2 side) as a distance from the reference position PO increases (in FIG. 9B, as advancing toward an arrow D2 side). Similarly to the resolution distribution in the deflection angle direction in the second portion 20B in the first embodiment, for the resolution (PPIf) in the deflection angle direction in the display region 20, a resolution rate is high in the vicinity of the reference position PO, and the resolution decreases as the distance from the reference position PO increases.

### 2-2 Action and Effect

In the display device 10 according to the second embodiment, similarly to the first embodiment, a resolution of a peripheral region can be made a low resolution, and an amount of processed data can be reduced.

### 3 Third Embodiment

### 3-1 Configuration of Display Device

In a display device 10 according to the third embodiment, as illustrated in FIG. 11A, for pixels 13A arranged in the same sectioned region 21, a configuration similar to that of the inner pixel 13AN in the first embodiment may be adopted. FIG. 11A is a plan view for explaining an implementation example of the display device according to the third embodiment.

Similarly to the display device 10 according to the first embodiment, the display device 10 according to the third embodiment includes a plurality of pixel columns 12A each having a plurality of pixels 13A arranged in a ring shape, and a display unit 11 having a display region 20. Furthermore, in the display unit 11, the plurality of pixel columns 12A is concentrically arranged along a plane direction of the display region 20, around a reference position PO in the display region 20 as a center. Note that, also in the third embodiment, as illustrated in FIG. 11A, a case where the pixel columns 12A are arranged concentrically will be described as an example.

In the display device 10 according to the third embodiment, in a case where the display region 20 is sectioned into a plurality of sectioned regions 21 with a boundary QA between adjacent pixel columns 12A, the pixels 13A arranged in the same sectioned region 21 have areas equal to each other, have lengths made equal to each other along a direction orthogonal to the alignment direction of the pixels 13A, and have pitches made equal to each other.

### (Sectioned Region)

The display region 20 illustrated in the example of FIG. 11A is sectioned into: a first sectioned region 21A in which a set of (t−1) pieces of pixel column 12A of the pixel columns 12A(1) . . . 12A(t−1) is arranged with the boundary QA between the pixel column 12A(t−1) and the pixel column 12A (t); and a second sectioned region 21B in which a set of (N−(t−1)) pieces of pixel column 12A of the pixel columns 12A(t) . . . 12A(N) is arranged. Note that, in a case where the first sectioned region 21A and the second sectioned region 21B are not particularly distinguished, the first sectioned region 21A and the second sectioned region 21B may be collectively referred to as the sectioned regions 21.

### (Area of Pixel and Length Along Radial Direction)

Areas of the pixels 13A arranged in the first sectioned region 21A are equal to each other. The point similarly applies to the second sectioned region 21B.

Furthermore, in the example of FIG. 11A, lengths Lr along the radial direction of the pixels 13A arranged in the first sectioned region 21A are made equal to each other. The point similarly applies to the second sectioned region 21B.

### (Pitch of Pixels)

Similarly to the description in the first embodiment, a pitch of the pixels 13A is determined by a pitch Pr in the radial direction and a pitch Pf in the deflection angle direction. The pitch Pr in the radial direction and the pitch Pf in the deflection angle direction of the pixels 13A arranged in the first sectioned region 21A have constant values. Furthermore, the pitch Pr in the radial direction and the pitch Pf in the deflection angle direction of the pixels 13A arranged in the second sectioned region 21B have constant values.

In the example of FIG. 11A, an arrangement of each pixel column 12A arranged in the first sectioned region 21A, an area of each pixel 13A in each pixel column 12A, and the like are determined such that the pitch Pr in the radial direction and the pitch Pf in the deflection angle direction of the pixels 13A arranged in the first sectioned region 21A are constant. An arrangement of each pixel column 12A of the pixels 13A arranged in the second sectioned region 21B, an area of each pixel 13A in each pixel column 12A, and the like are determined such that the pitch Pr in the radial direction and the pitch Pf in the deflection angle direction of the pixels 13A arranged in the second sectioned region 21B are constant.

Furthermore, among the adjacent sectioned regions 21 (the first sectioned region 21A and the second sectioned region 21B), a pitch of the pixels 13A arranged in the sectioned region 21 (the first sectioned region 21A) located on the inner side is smaller than a pitch of the pixels 13A arranged in the sectioned region 21 (the second sectioned region 21B) located on the outer side. That is, a pitch in the radial direction of the pixels 13A arranged in the first sectioned region 21A is smaller than a pitch in the radial direction of the pixels 13A arranged in the second sectioned region 21B. Furthermore, a pitch in the deflection angle direction of the pixels 13A arranged in the first sectioned region 21A is smaller than a pitch in the deflection angle direction of the pixels 13A arranged in the second sectioned region 21B.

### (Resolution Distribution)

In the display device 10 according to the third embodiment, a resolution distribution for the resolution (PPIr) in the radial direction in the display region 20 is determined similarly to the first embodiment. In the display device 10 according to the third embodiment, as illustrated in FIG. 11B, the resolution (PPIr) in the radial direction in each of the first sectioned region 21A and the second sectioned region 21B in the display region 20 is approximately constant. This can be achieved by adjusting a pitch and an area of the pixels 13A arranged in each of the first sectioned region 21A and the second sectioned region 21B, and the number of the pixels 13A arranged in each pixel column 12A. Note that FIG. 11B illustrates an example of the resolution distribution in the radial direction corresponding to the arrangement of the pixels 13A in the display device 10 illustrated in the example of FIG. 11A. Furthermore, in FIG. 11B, a broken line indicates a case where a distance (a distance in the +r direction) from the reference position along the radial direction is a distance from the boundary QA between the first sectioned region 21A and the second sectioned region 21B to the reference position PO. A region closer to the reference position PO from the boundary QA (in FIG. 10B, an arrow D1 side) indicates a resolution of the first sectioned region 21A, and a region having a longer distance from the boundary QA to the reference position PO (in FIG. 3B, on an arrow D2 side) indicates a resolution of the second sectioned region 21B.

As illustrated in FIG. 10B, the resolution (PPIr) in the radial direction in the first sectioned region 21A is larger than the resolution (PPIr) in the radial direction in the second sectioned region 21B (in FIG. 11B, a value of the resolution (PPIr) in the radial direction in the first sectioned region 21A is a value on an arrow H1 side from a value of the resolution (PPIr) in the radial direction in the second sectioned region 21B). Therefore, in the display device 10 according to the third embodiment, as illustrated in FIG. 11B, the resolution in the radial direction changes stepwise such that the resolution is lower at a position farther from the reference position PO than that at a position closer to the reference position PO.

A distribution of the resolution (PPIf) in the deflection angle direction in the display region 20 is determined similarly to the first embodiment. In the display device 10 according to the third embodiment, a resolution distribution in the deflection angle direction in the display region 20 is a resolution distribution similar to that of the example of the resolution distribution in the radial direction illustrated in FIG. 11B.

### (Sub-Pixel)

In the display device 10 according to the third embodiment, similarly to the first embodiment, the pixel 13A may have sub-pixels 16 of a plurality of color types. Here, the description will be continued with a case as an example in which three colors of a red sub-pixel 16R, a green sub-pixel 16G, and a blue sub-pixel 16B are determined as a plurality of sub-pixels 16 forming one pixel 13A. Note that, similarly to the first embodiment, the color sub-pixel 16R, the green sub-pixel 16G, and the blue sub-pixel 16B may be collectively referred to as the sub-pixels 16.

In the display device 10 according to the third embodiment, an arrangement of the sub-pixels 16 arranged in the same sectioned region 21 may be similar to the arrangement of the sub-pixels 16 in the inner pixel 13AN in a case where the inner pixel 13AN of the display device 10 according to the first embodiment has the sub-pixels 16. Therefore, in the display device 10 according to the third embodiment, an arrangement of the sub-pixels 16 arranged in the same sectioned region 21 may be similar to the arrangement illustrated in FIGS. 5B and 6B, for example.

In a case where the pixel 13A has the sub-pixels 16 of the plurality of color types, for every color type of the sub-pixels 16, the sub-pixels 16 forming the pixels 13A arranged in the same sectioned region 21 have areas equal to each other, and lengths along a direction orthogonal to the alignment direction of the pixels 13A in each pixel column 12A are made equal to each other.

In the display device 10, the red sub-pixels 16R arranged in the first sectioned region 21A have areas equal to each other, and the lengths Lr of the red sub-pixels 16R along the radial direction are also equal to each other. This similarly applies to the green sub-pixel 16G and the blue sub-pixel 16B arranged in the first sectioned region 21A.

Furthermore, the red sub-pixels 16R arranged in the second sectioned region 21B have areas equal to each other, and the lengths Lr of the red sub-pixels 16R along the radial direction are also equal to each other. This similarly applies to the green sub-pixel 16G and the blue sub-pixel 16B arranged in the second sectioned region 21B.

In the display device 10 according to the third embodiment, even in a case where the pixel 13A has the sub-pixel 16, a resolution distribution of the display region 20 can be set to the resolution distribution as illustrated in FIG. 11B.

### 3-2 Action and Effect

In the display device 10 according to the third embodiment, the pixel columns 12A are concentrically arranged around the reference position PO as a center in the display region 20, and are sectioned into a plurality of sectioned regions 21 between predetermined adjacent pixel columns 12A. A resolution in each sectioned region 21 is constant. Further, in the adjacent sectioned regions 21, a resolution of the sectioned region 21 (the first sectioned region 21A) closer to the reference position PO is higher than a resolution of the sectioned region 21 (the second sectioned region 21B) closer to the reference position PO. Therefore, according to the third embodiment, it is easy to respectively align the first sectioned region 21A and the second sectioned region 21B with a region (a center region) that is easily perceived by human vision and a region (a peripheral region) on the outer side thereof. Therefore, high-resolution display can be achieved for the center region, and an amount of processed data can be reduced by performing low-resolution display for the peripheral region.

### 3-3 Modification

In the display device 10 according to the third embodiment, the number of the sectioned regions 21 may be three or more (not illustrated) (a modification). Also in this case, a resolution in each sectioned region 21 is individually constant. Further, in the adjacent sectioned regions 21, a resolution of the sectioned region 21 closer to the reference position PO is higher than a resolution of the sectioned region 21 closer to the reference position PO. Furthermore, in the display device according to the third embodiment, a resolution in the radial direction changes stepwise such that a resolution of the display region 20 becomes lower at a position farther from the reference position PO than that at a position closer to the reference position PO. In a case where the number of the sectioned regions 21 is three, the resolution in the radial direction and the resolution in the deflection angle direction change stepwise in two stages.

Also in the modification of the display device according to the third embodiment, effects similar to those of the third embodiment can be obtained.

### 4 Application Example

### (Electronic Device)

The display device 10 according to one embodiment described above may be provided in various electronic devices. In particular, the display device 10 is preferably provided in a device that requires high resolution and is used near the eyes by enlarging, such as electronic binoculars, eyeglass-type displays for VR, eyeglass-type displays for AR, head-mounted type (HMD-type) displays, and the like.

### (Specific Examples)

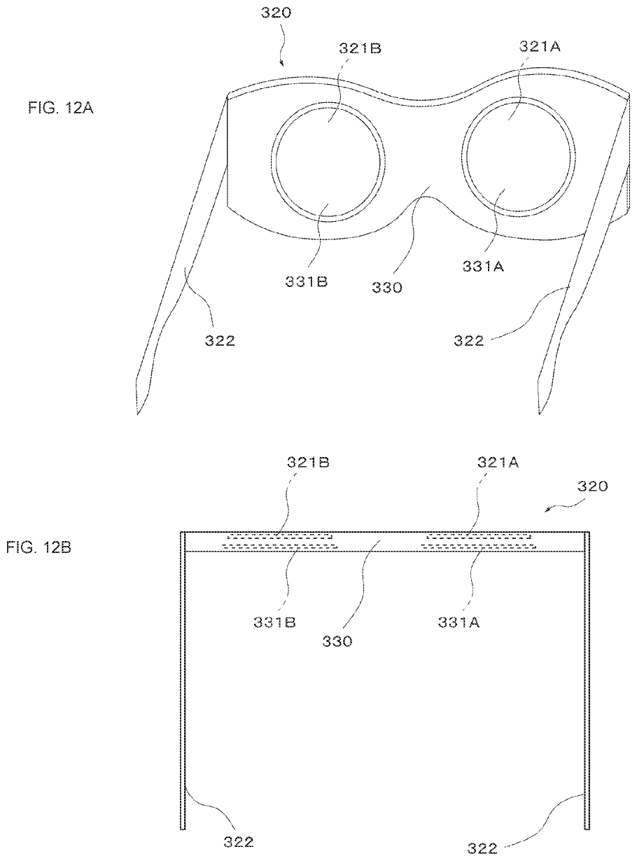

FIG. 12A is a perspective view illustrating an example of an appearance of an eyeglass-type display 320 applicable to VR or AR. FIG. 12B is a plan view illustrating an example of an external appearance of the display 320. The display 320 includes, for example, an eyeglass-shaped holder 330, is provided with display units 321A and 321B at positions corresponding to eye portions in the holder 330, and optical systems 331A and 331B closer to eye portions of the user with respect to the display units 321A and 321B, and has ear hooking portions 322 to be mounted on a head part of the user on both sides of the holder 330. In the display 320, any one of the display devices 10 according to the above-described embodiment and modifications can be used for at least one of the display unit 321A on the right eye side and the display unit 321B on the left eye side.

Although the display devices and the application examples according to the first to third embodiments and each modification of the present disclosure have been specifically described above, the present disclosure is not limited to the display devices and the application examples according to the first to third embodiments and each modification described above, and various modifications based on the technical idea of the present disclosure are possible.

For example, the configurations, methods, steps, shapes, materials, numerical values, and the like given in the display devices and the application examples according to the first to third embodiments and each modification are merely examples, and different configurations, methods, steps, shapes, materials, numerical values, and the like may be used as necessary.

The configurations, methods, steps, shapes, materials, numerical values, and the like of the display devices and the application examples according to the first to third embodiments and each modification can be combined with each other without departing from the gist of the present disclosure.

The materials exemplified in the display devices and the application examples according to the first to third embodiments and each modification can be used alone or in combination of two or more unless otherwise specified.

Furthermore, the present disclosure can also adopt the following configurations.

(1) A display device including:
a display unit having a display region in which a plurality of pixel columns is arranged, in which
each of a plurality of the pixel columns has a plurality of pixels arranged in a ring shape,
in the display unit, a plurality of the pixel columns is concentrically arranged along a plane direction of the display region, the plurality of the pixel columns being arranged around, as a center, a reference position in the display region, and
in a case where a pixel column arranged at a predetermined position in a plurality of the pixel columns is defined as a reference pixel column, and each of the pixels forming the reference pixel column is defined as a reference pixel,
each of the pixels forming each of the pixel columns arranged on an outer side of the reference pixel column has a similar shape obtained by enlarging a shape of the reference pixel.

(2) A display device including:
a display unit having a display region in which a plurality of pixel columns is arranged, in which
each of a plurality of the pixel columns has a plurality of pixels arranged in a ring shape,
in the display unit, a plurality of the pixel columns is concentrically arranged along a plane direction of the display region, the plurality of the pixel columns being arranged around, as a center, a reference position in the display region,
in a case where the display region is sectioned into a plurality of sectioned regions with a boundary between the pixel columns adjacent to each other,
the pixels arranged in a same sectioned region have areas equal to each other, have lengths made equal to each other along a direction orthogonal to an alignment direction of the pixels, and have pitches made equal to each other, and
among the sectioned regions adjacent to each other, a pitch of the pixels arranged in each of the sectioned regions arranged on an inner side is smaller than a pitch of the pixels arranged in each of the sectioned regions arranged on an outer side.

(3) The display device according to (1) described above, in which
among the pixel columns adjacent to each other arranged on an outer side of the reference pixel column, a similarity ratio of a size of each of the pixels forming each of the pixel columns on an outer side to a size of each of the pixels forming each of the pixel columns on an inner side coincides with a similarity ratio of a size of each of the pixels forming each of the pixel columns adjacent to the reference pixel column on an outer side of the reference pixel column to a size of the reference pixel.

(4) The display device according to (1) or (3) described above, in which
each of the pixels has sub-pixels of a plurality of color types, and
for every color type of the sub-pixels, each of the sub-pixels arranged on an outer side of the reference pixel column has a similar shape obtained by enlarging a shape of each of the sub-pixels forming the reference pixel.

(5) The display device according to (4) described above, in which
for every color type of the sub-pixels, among the pixel columns adjacent to each other arranged on an outer side of the reference pixel column, a similarity ratio of a size of each of the sub-pixels forming each of the pixel columns on an outer side to a size of each of the sub-pixels forming each of the pixel columns on an inner side coincides with a reference similarity ratio that is defined as a similarity ratio of a size of each of the sub-pixels forming each of the pixel columns adjacent to the reference pixel column on an outer side of the reference pixel column to a size of each of the sub-pixels forming the reference pixel column, and
the reference similarity ratio coincides between the sub-pixels of different color types.

(6) The display device according to any one of (1) and (3) to (5) described above, in which
each of the pixels has sub-pixels of a plurality of color types, and
for every color type of the sub-pixels, among the pixel columns adjacent to each other arranged on an outer side of the reference pixel column, each of the sub-pixels forming one of the pixel columns is arranged at a position avoiding a position to be aligned, in an inner and outer direction, with a position of each of the sub-pixels forming another one of the pixel columns.

(7) The display device according to any one of (1) and (3) to (6) described above, in which
the reference pixel column is a pixel column among the pixel columns arranged at a position closest to the reference position.

(8) The display device according to any one of (1) and (3) to (6) described above, in which
inner pixels defined as the pixels arranged on an inner side of the reference pixel column have areas equal to each other, the inner pixels having lengths made equal to each other along a direction orthogonal to an alignment direction of the pixels in each of the pixel columns, and pitches of the inner pixels are equal to each other.

(9) The display device according to (8) described above, in which
each of the pixels has sub-pixels of a plurality of color types, and
for every color type of the sub-pixels, the sub-pixels forming the inner pixels have areas equal to each other, and have lengths made equal to each other along a direction orthogonal to an alignment direction of the pixels in each of the pixel columns.

(10) The display device according to any one of (1) and (3) to (9) described above, in which
each of the pixels has sub-pixels of a plurality of color types, and
for every color type of the sub-pixels, among the pixel columns arranged adjacent to each other on an inner side of the reference pixel column, each of the sub-pixels forming one of the pixel columns is arranged at a position avoiding a position to be aligned, in an inner and outer direction, with a position of each of the sub-pixels forming another one of the pixel columns.

(11) The display device according to (2) described above, in which
a number of the sectioned regions is three or more.

(12) The display device according to (2) or (11) described above, in which
each of the pixels has sub-pixels of a plurality of color types, and
for every color type of the sub-pixels, the sub-pixels forming the pixels arranged in a same sectioned region have areas equal to each other and have lengths made equal to each other along a direction orthogonal to an alignment direction of the pixels in each of the pixel columns.

(13) The display device according to any one of (1) to (12) described above, in which
each of the pixels has a plurality of sub-pixels, and
for each one of the pixels, a plurality of the sub-pixels is arranged in each direction among an alignment direction of the pixels forming each of the pixel columns and a direction orthogonal to the alignment direction.

(14) The display device according to any one of (1) to (13) described above, in which
a plurality of the pixel columns is arranged concentrically.

(15) An electronic device including:
the display device according to any one of (1) to (14) described above.

### REFERENCE SIGNS LIST

10 Display device
11 Display unit
12A Pixel column
12AX Reference pixel column
13A Pixel
13AN Inner pixel
13AX Reference pixel
14 Central pixel
16 Sub-pixel
16B Sub-pixel
16G Sub-pixel
16R Sub-pixel
20 Display region
20A First portion
20B Second portion
21 Sectioned region
21A First sectioned region
21B Second sectioned region
320 Display
321A Display unit
321B Display unit
322 Ear hooking portion
330 Holder
331A Optical system
331B Optical system

1. A display device comprising:
a display unit having a display region in which a plurality of pixel columns is arranged, wherein
each of a plurality of the pixel columns has a plurality of pixels arranged in a ring shape,
in the display unit, a plurality of the pixel columns is concentrically arranged along a plane direction of the display region, the plurality of the pixel columns being arranged around, as a center, a reference position in the display region, and
in a case where a pixel column among the pixel columns arranged at a predetermined position in a plurality of the pixel columns is defined as a reference pixel column, and each of the pixels forming the reference pixel column is defined as a reference pixel,
each of the pixels forming each of the pixel columns arranged on an outer side of the reference pixel column has a similar shape obtained by enlarging a shape of the reference pixel.

2. A display device comprising:
a display unit having a display region in which a plurality of pixel columns is arranged, wherein
each of a plurality of the pixel columns has a plurality of pixels arranged in a ring shape,
in the display unit, a plurality of the pixel columns is concentrically arranged along a plane direction of the display region, the plurality of the pixel columns being arranged around, as a center, a reference position in the display region,
in a case where the display region is sectioned into a plurality of sectioned regions with a boundary between the pixel columns adjacent to each other,
the pixels arranged in a same sectioned region among the sectioned regions have areas equal to each other, have lengths made equal to each other along a direction orthogonal to an alignment direction of the pixels, and have pitches made equal to each other, and
among the sectioned regions adjacent to each other, a pitch of the pixels arranged in each of the sectioned regions arranged on an inner side is smaller than a pitch of the pixels arranged in each of the sectioned regions arranged on an outer side.

3. The display device according to claim 1, wherein
among the pixel columns adjacent to each other arranged on an outer side of the reference pixel column, a similarity ratio of a size of each of the pixels forming each of the pixel columns on an outer side to a size of each of the pixels forming each of the pixel columns on an inner side coincides with a similarity ratio of a size of each of the pixels forming each of the pixel columns adjacent to the reference pixel column on an outer side of the reference pixel column to a size of the reference pixel.

4. The display device according to claim 1, wherein
each of the pixels has sub-pixels of a plurality of color types, and
for every color type of the sub-pixels, each of the sub-pixels arranged on an outer side of the reference pixel column has shape of a similar shape obtained by enlarging a shape of each of the sub-pixels forming the reference pixel.

5. The display device according to claim 4, wherein
for every color type of the sub-pixels, among the pixel columns adjacent to each other arranged on an outer side of the reference pixel column, a similarity ratio of a size of each of the sub-pixels forming each of the pixel columns on an outer side to a size of each of the sub-pixels forming each of the pixel columns on an inner side coincides with a reference similarity ratio that is defined as a similarity ratio of a size of each of the sub-pixels forming each of the pixel columns adjacent to the reference pixel column on an outer side of the reference pixel column to a size of each of the sub-pixels forming the reference pixel column, and
the reference similarity ratio coincides between the sub-pixels of different color types.

6. The display device according to claim 1, wherein each of the pixels has sub-pixels of a plurality of color types, and
for every color type of the sub-pixels, among the pixel columns adjacent to each other arranged on an outer side of the reference pixel column, each of the sub-pixels forming one of the pixel columns is arranged at a position avoiding a position to be aligned, in an inner and outer direction, with a position of each of the sub-pixels forming another one of the pixel columns.

7. The display device according to claim 1, wherein
the reference pixel column is a pixel column among the pixel columns arranged at a position closest to the reference position.

8. The display device according to claim 1, wherein
inner pixels defined as the pixels arranged on an inner side of the reference pixel column have areas equal to each other, the inner pixels having lengths made equal to each other along a direction orthogonal to an alignment direction of the pixels in each of the pixel columns, and pitches of the inner pixels are equal to each other.

9. The display device according to claim 8, wherein
each of the pixels has sub-pixels of a plurality of color types, and
for every color type of the sub-pixels, the sub-pixels forming the inner pixels have areas equal to each other, and have lengths made equal to each other along a direction orthogonal to an alignment direction of the pixels in each of the pixel columns.

10. The display device according to claim 1, wherein
each of the pixels has sub-pixels of a plurality of color types, and
for every color type of the sub-pixels, among the pixel columns arranged adjacent to each other on an inner side of the reference pixel column, each of the sub-pixels forming one of the pixel columns is arranged at a position avoiding a position to be aligned, in an inner and outer direction, with a position of each of the sub-pixels forming another one of the pixel columns.

11. The display device according to claim 2, wherein a number of the sectioned regions is three or more.

12. The display device according to claim 2, wherein
each of the pixels has sub-pixels of a plurality of color types, and
for every color type of the sub-pixels, the sub-pixels forming the pixels arranged in a same sectioned region among the sectioned regions have areas equal to each other and have lengths made equal to each other along a direction orthogonal to an alignment direction of the pixels in each of the pixel columns.

13. The display device according to claim 1, wherein
each of the pixels has a plurality of sub-pixels, and
for one of the pixels, a plurality of the sub-pixels is arranged in each direction among an alignment direction of the pixels forming each of the pixel columns and a direction orthogonal to the alignment direction.

14. The display device according to claim 1, wherein
a plurality of the pixel columns is arranged concentrically.

15. An electronic device comprising:
the display device according to claim 1.
